(19) United States
(12) Patent Application Publication
(10) Pub. No.: US 2024/0222123 A1
(43) Pub. Date: Jul. 4, 2024

(54) METHOD OF FABRICATING SEMICONDUCTOR DEVICE

(71) Applicant: Samsung Electronics Co., Ltd., Suwon-si (KR)

(72) Inventors: Kang In KIM, Suwon-si (KR); Si Nyeon KIM, Suwon-si (KR); Jiho PARK, Suwon-si (KR); Youngwoo SON, Suwon-si (KR); Ji-Eun LEE, Suwon-si (KR); Young-Seung CHO, Suwon-si (KR)

(73) Assignee: Samsung Electronics Co., Ltd., Suwon-si (KR)

(21) Appl. No.: 18/356,322

(22) Filed: Jul. 21, 2023

(30) Foreign Application Priority Data
Dec. 29, 2022 (KR) 10-2022-0189650

(51) Int. Cl. H01L 21/033; H01L 21/308; H01L 21/311; H01L 29/423; H01L 29/66

(52) U.S. Cl. CPC H01L 21/0337; H01L 21/0332; H01L 21/3086; H01L 21/31144; H01L 29/4236; H01L 29/6653; H01L 29/6656

(57) ABSTRACT

A method of fabricating a semiconductor device may include forming an active pattern on a substrate, sequentially forming on the substrate a base mask, a first mask layer, a first capping layer, a second mask layer, a second capping layer, a third mask layer, a third capping layer, a fourth mask layer, and a fourth capping layer, forming first spacers, forming second spacers, forming third spacers, and using the third spacers as a mask to pattern the first mask layer and the first capping layer. Forming the third spacers may include forming a spacer layer to completely fill a space between the sidewalls of patterns of the patterned second mask layer.

### CROSS-REFERENCE TO RELATED APPLICATION

This U.S. nonprovisional application claims priority under 35 U.S.C § 119 to Korean Patent Application No. 10-2022-0189650, filed on Dec. 29, 2022 in the Korean Intellectual Property Office, the disclosure of which is hereby incorporated by reference in its entirety.

### BACKGROUND

Inventive concepts relate to a method of fabricating a semiconductor device, and more particularly, to a method of fabricating a semiconductor device in which a spacer is used as a mask to pattern a mask layer.

Semiconductor devices have an important role in the electronic industry because of their small size, multi-functionality, and/or low fabrication cost. The semiconductor devices may be categorized as any one of semiconductor memory devices storing logic data, semiconductor logic devices processing operations of logic data, and hybrid semiconductor devices having both memory and logic elements.

Along with the recent trend toward higher speed and low power consumption in electronic products, semiconductor devices in electronic appliances may need high operating speed and/or low operating voltage, and concurrently high integration of semiconductor devices also may be required to achieve compactness of electronic products. Accordingly, various studies are being conducted to accomplish mass production of fine semiconductor devices and to increase reliability and electrical properties of semiconductor devices.

### SUMMARY

Some embodiments of inventive concepts provide a method of fabricating a semiconductor device with improved electrical properties.

Some embodiments of inventive concepts provide a method of fabricating a semiconductor device with increased reliability.

Aspects of inventive concepts are not limited to those mentioned above, and other aspects that have not been mentioned above will be clearly understood to those skilled in the art from the following description.

According to some embodiments of inventive concepts, a method of fabricating a semiconductor device may include forming an active pattern on a substrate; sequentially forming on the substrate a base mask, a first mask layer, a first capping layer, a second mask layer, a second capping layer, a third mask layer, a third capping layer, a fourth mask layer, and a fourth capping layer; patterning the fourth mask layer and the fourth capping layer, the patterning the fourth mask layer providing a patterned fourth mask layer; forming a plurality of first spacers on sidewalls of the patterned fourth mask layer; using the first spacers as a mask to pattern the third mask layer and the third capping layer such that a patterned third mask layer and a patterned third capping layer are provided; forming a plurality of second spacers on sidewalls of the patterned third mask layer; using the second spacers as a mask to pattern the second mask layer and the second capping layer such that a patterned second mask layer and a patterned second capping layer are provided; forming a plurality of third spacers on sidewalls of the patterned second mask layer; using the third spacers as a mask to pattern the first mask layer and the first capping layer such that a patterned first mask layer and a patterned first capping layer are provided; using the patterned first mask layer and the patterned first capping layer as a mask to pattern the base mask such that a patterned base mask is provided; using the patterned base mask as a mask to etch a trench in the active pattern; and forming a gate structure in the trench. The forming the plurality of third spacers may include forming a spacer layer to completely fill a space between the sidewalls of the patterned second mask layer.

According to some embodiments of inventive concepts, a method of fabricating a semiconductor device may include forming an active pattern on a substrate; sequentially forming on the substrate a base mask, a first mask layer, a first capping layer, a second mask layer, a second capping layer, a third mask layer, and a third capping layer; patterning the third mask layer and the third capping layer; forming a plurality of first spacers on sidewalls of the third mask layer; using the first spacers as a mask to pattern the second mask layer and the second capping layer such that a patterned second mask layer and a patterned second capping layer are provided; forming a plurality of second spacers on sidewalls of the patterned second mask layer; using the second spacers as a mask to pattern the first mask layer and the first capping layer such that a patterned first mask layer and a patterned first capping layer are provided; using the patterned first mask layer and the patterned first capping layer as a mask to pattern the base mask such that a patterned base mask is provided; and forming a trench in the active pattern using the patterned base mask as a mask. The forming the plurality of second spacers may include forming a spacer layer on the patterned second mask layer and the patterned second capping layer, and etching the spacer layer. The spacer layer may have a first curved surface and a second curved surface that may be in contact with each other. A contact point between the first curved surface and the second curved surface may be between patterns of the patterned second mask layer.

According to some embodiments of inventive concepts, a method of fabricating a semiconductor device may include forming an active pattern on a substrate; sequentially forming on the substrate a base mask, a first mask layer, a first capping layer, a second mask layer, a second capping layer, a third mask layer, a third capping layer, a fourth mask layer, and a fourth capping layer; patterning the fourth mask layer and the fourth capping layer, the patterning the fourth mask layer and the fourth capping layer providing a patterned fourth mask layer and a patterned fourth capping layer; forming a plurality of first spacers on sidewalls of the patterned fourth mask layer and sidewalls of the patterned fourth capping layer; removing the patterned fourth mask layer and the patterned fourth capping layer; using the first spacers as a mask to pattern the third mask layer and the third capping layer such that a patterned third mask layer and a patterned third capping layer are provided; forming a plurality of second spacers on sidewalls of the patterned third mask layer and sidewalls of the patterned third capping layer; removing the patterned third mask layer and the patterned third capping layer; using the second spacers as a mask to pattern the second mask layer and the second capping layer such that a patterned second mask layer and a patterned second capping layer are provided; depositing a spacer layer that completely fills spaces between patterns of the patterned second mask layer and fills spaces between patterns of the patterned second capping layer; removing an upper portion of the spacer layer to form a plurality of third spacers; removing the patterned second mask layer and the patterned second capping layer; using the third spacers as a mask to pattern the first mask layer and the first capping layer such that a patterned first mask layer and a patterned first capping layer are provided; using the patterned first mask layer and the patterned first capping layer to pattern the base mask such that a patterned base mask is provided; and using the patterned base mask to form a trench in the active pattern.

### BRIEF DESCRIPTION OF DRAWINGS

FIG. 1 illustrates a flow chart showing a method of fabricating a semiconductor device according to some embodiments of inventive concepts.

FIGS. 2A, 3A, 3E, 3I, 4A, 4E, 5A, 6A, 7A, 8A, 9A, 10A, and 11A illustrate plan views showing a method of fabricating a semiconductor device according to some embodiments of inventive concepts.

FIGS. 2B, 3B, 3F, 3J, 4B, 4F, 5B, 6B, 7B, 8B, 9B, 10B, and 11B illustrate cross-sectional views taken along line A-A′ of FIGS. 2A, 3A, 3E, 3I, 4A, 4E, 5A, 6A, 7A, 8A, 9A, 10A, and 11A, respectively.

FIGS. 2C, 3C, 3G, 3K, 4C, 4G, 5C, 6C, 7C, 8C, 9C, 10C, and 11C illustrate cross-sectional views taken along line B-B′ of FIGS. 2A, 3A, 3E, 3I, 4A, 4E, 5A, 6A, 7A, 8A, 9A, 10A, and 11A, respectively.

FIGS. 2D, 3D, 3H, 3L, 4D, 4H, 5D, 6D, 7D, 8D, 9D, 10D, and 11D illustrate cross-sectional views taken along line C-C′ of FIGS. 2A, 3A, 3E, 3I, 4A, 4E, 5A, 6A, 7A, 8A, 9A, 10A, and 11A, respectively.

FIG. 5E illustrates an enlarged view showing section Q of FIG. 5D.

### DETAILED DESCRIPTION

Some embodiments of inventive concepts will now be described in detail with reference to the accompanying drawings to aid in clearly explaining inventive concepts.

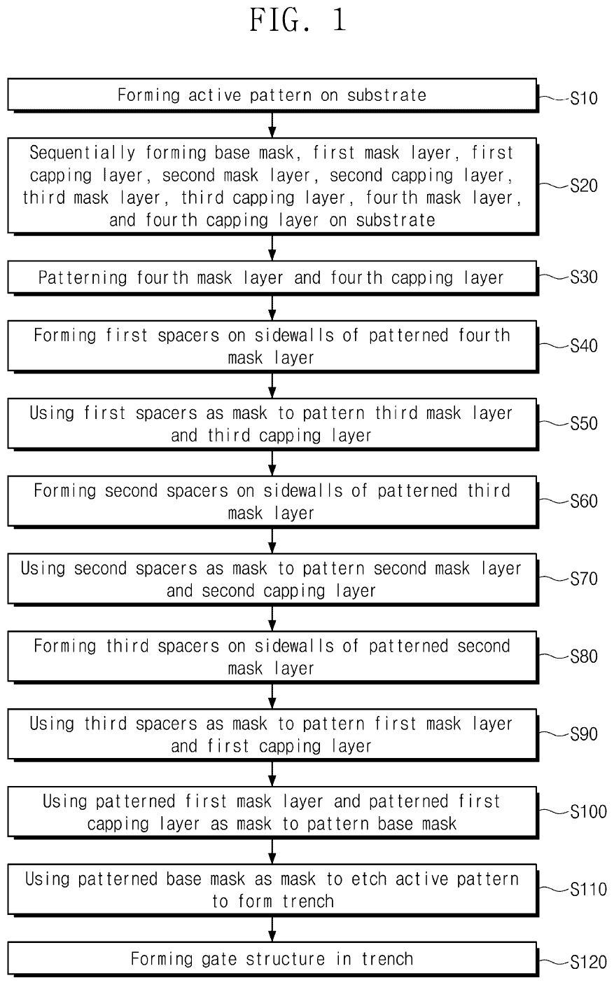

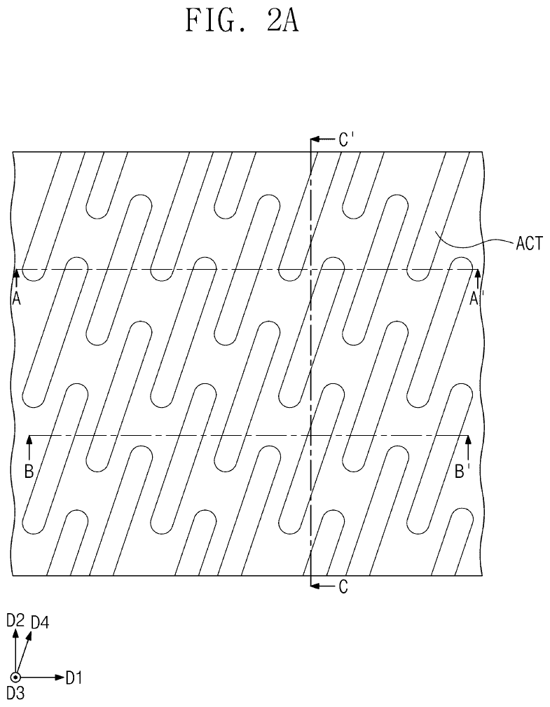

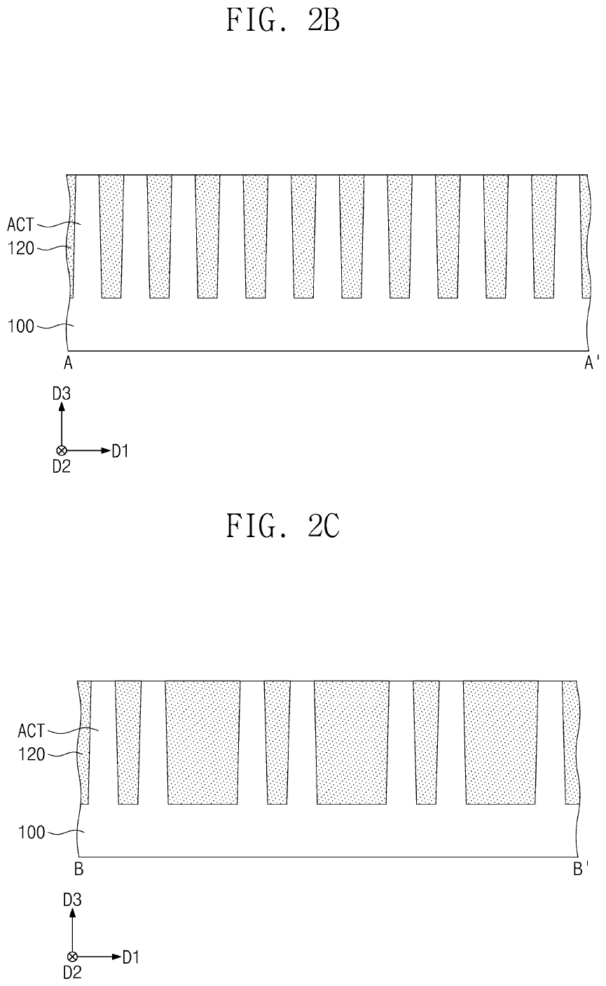

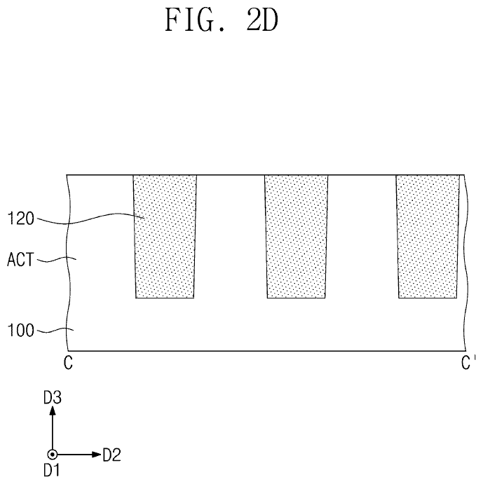

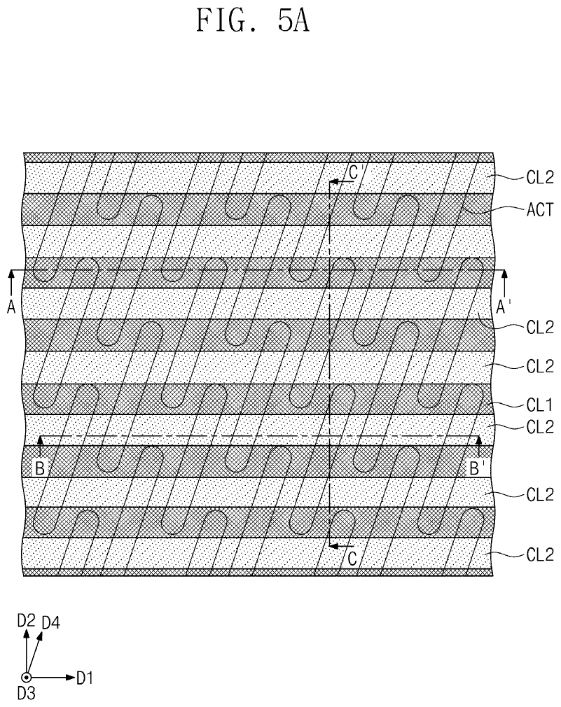

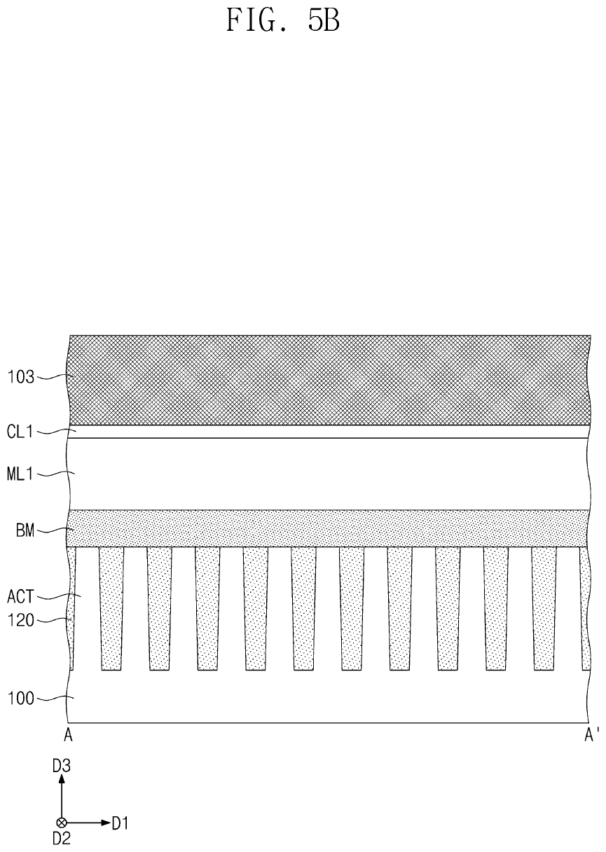

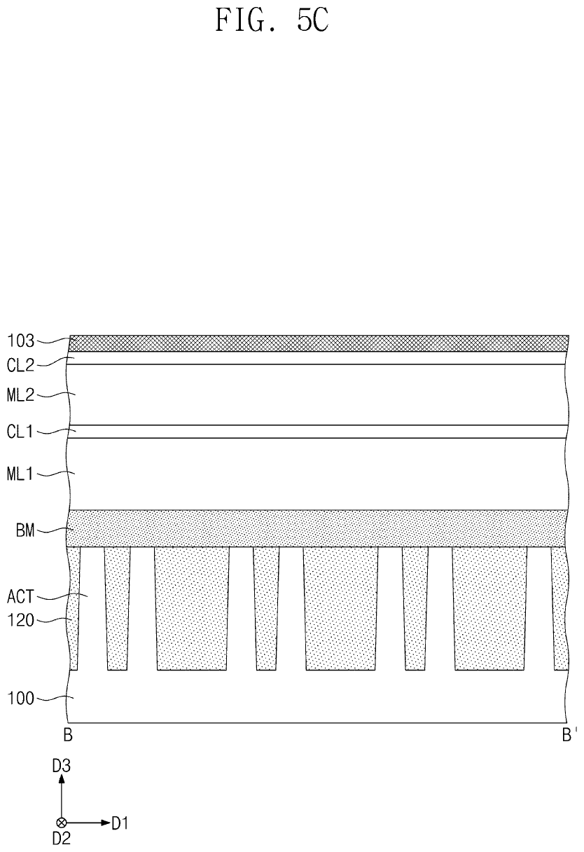

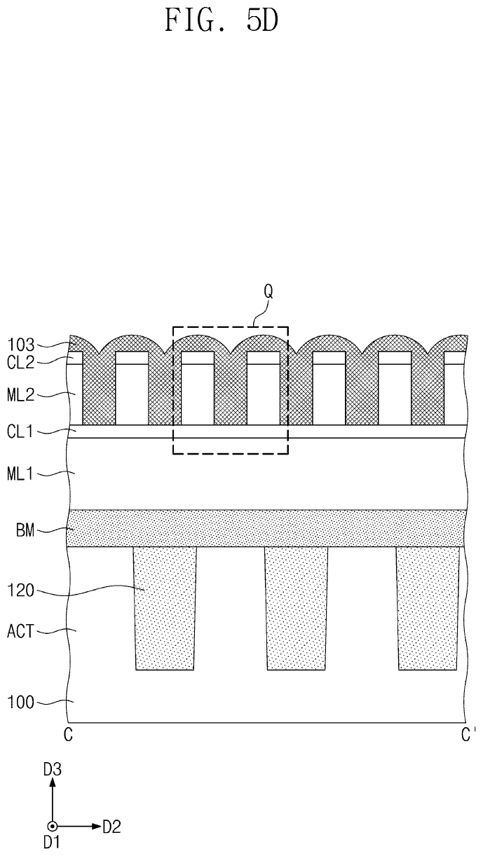

FIG. 1 illustrates a flow chart showing a method of fabricating a semiconductor device according to some embodiments of inventive concepts. FIGS. 2A to 11D illustrate plan and cross-sectional views showing a method of fabricating a semiconductor device according to some embodiments of inventive concepts. For example, FIGS. 2A, 3A, 3E, 3I, 4A, 4E, 5A, 6A, 7A, 8A, 9A, 10A, and 11A illustrate plan views showing a method of fabricating a semiconductor device according to some embodiments of inventive concepts. FIGS. 2B, 3B, 3F, 3J, 4B, 4F, 5B, 6B, 7B, 8B, 9B, 10B, and 11B illustrate cross-sectional views taken along line A-A′ of FIGS. 2A, 3A, 3E, 3I, 4A, 4E, 5A, 6A, 7A, 8A, 9A, 10A, and 11A, respectively. FIGS. 2C, 3C, 3G, 3K, 4C, 4G, 5C, 6C, 7C, 8C, 9C, 10C, and 11C illustrate cross-sectional views taken along line B-B′ of FIGS. 2A, 3A, 3E, 3I, 4A, 4E, 5A, 6A, 7A, 8A, 9A, 10A, and 11A, respectively. FIGS. 2D, 3D, 3H, 3L, 4D, 4H, 5D, 6D, 7D, 8D, 9D, 10D, and 11D illustrate cross-sectional views taken along line C-C′ of FIGS. 2A, 3A, 3E, 3I, 4A, 4E, 5A, 6A, 7A, 8A, 9A, 10A, and 11A, respectively. FIG. 5E illustrates an enlarged view showing section Q of FIG. 5D.

Referring to FIGS. 1 and 2A to 2D, a substrate 100 may be provided. The substrate 100 may be a semiconductor substrate, for example, one of a silicon substrate, a germanium substrate, and a silicon-germanium substrate. The substrate 100 may have a plate shape elongated along a plane defined by a first direction D1 and a second direction D2. The first direction D1 and the second direction D2 may intersect each other. For example, the first direction D1 and the second direction D2 may be orthogonal to each other. However, example embodiments are not limited thereto. For example, the substrate 100 may have a wafer shape.

Active patterns ACT may be formed on the substrate (S10). Each of the active patterns ACT may have a linear shape that extends in a fourth direction D4. The fourth direction D4 may intersect the first direction D1 and the second direction D2. For example, the fourth direction D4 may be parallel to a plane defined by the first direction D1 and the second direction D2. The active patterns ACT may be defined to indicate upper portions of the substrate 100 that protrude in the third direction D3. The third direction D3 may intersect the first direction D1, the second direction D2, and the fourth direction D4. For example, the third direction D3 may intersect the first direction D1, the second direction D2, and the fourth direction D4. The active patterns ACT may be spaced apart from each other.

A device isolation pattern 120 may be formed in a space provided between the active patterns ACT, and may be buried in an upper portion of the substrate 100. The formation of the device isolation pattern 120 may include performing a patterning process to partially remove an upper portion of the substrate 100, and filling the removed region with the device isolation pattern 120. The device isolation pattern 120 may be a single layer or a multiple layer including two or more materials.

The active patterns ACT may be defined by the device isolation pattern 120. Each of the active patterns ACT may be surrounded by the device isolation pattern 120. The device isolation pattern 120 may separate the active patterns ACT from each other.

The device isolation pattern 120 may include a dielectric material. The device isolation pattern 120 may include at least one selected from, for example, silicon oxide, silicon nitride, and silicon oxynitride. For convenience of description, the substrate 100 is defined to indicate a region of the substrate 100 (or a lower portion of the substrate 100) other than the active patterns ACT. An ion implantation process may implant the active patterns ACT with impurities.

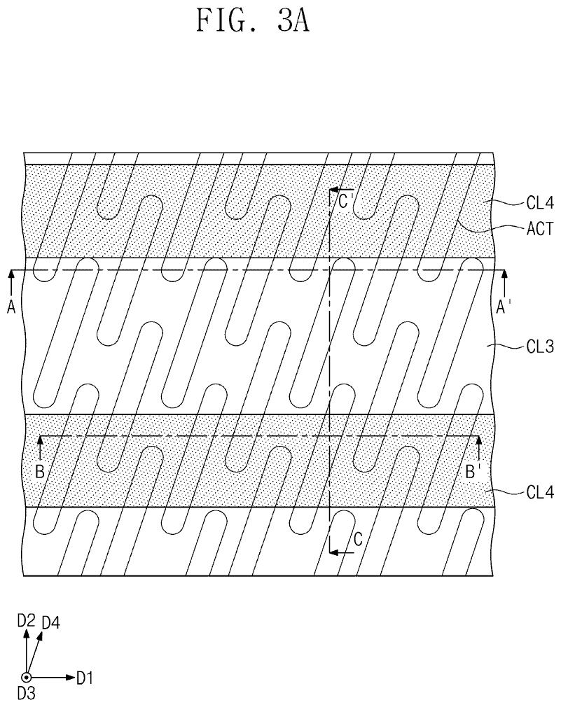

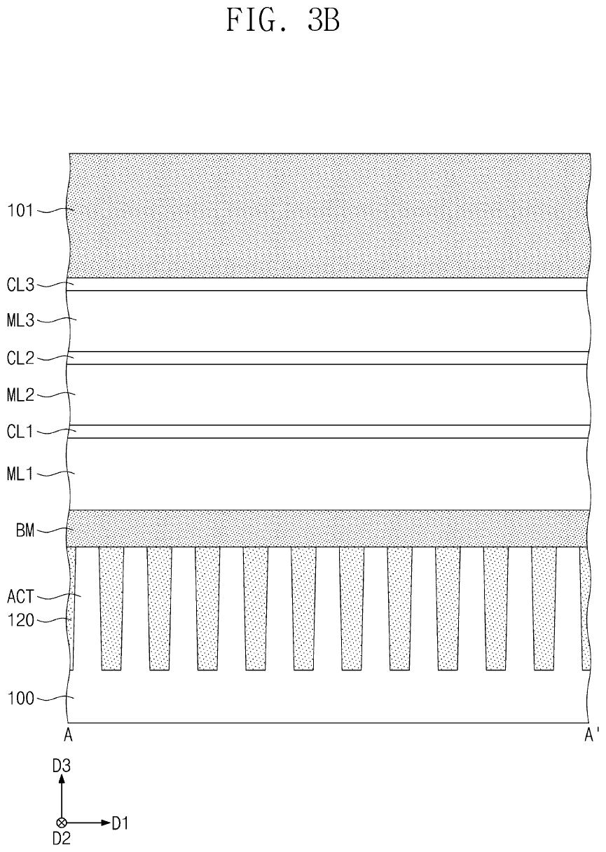

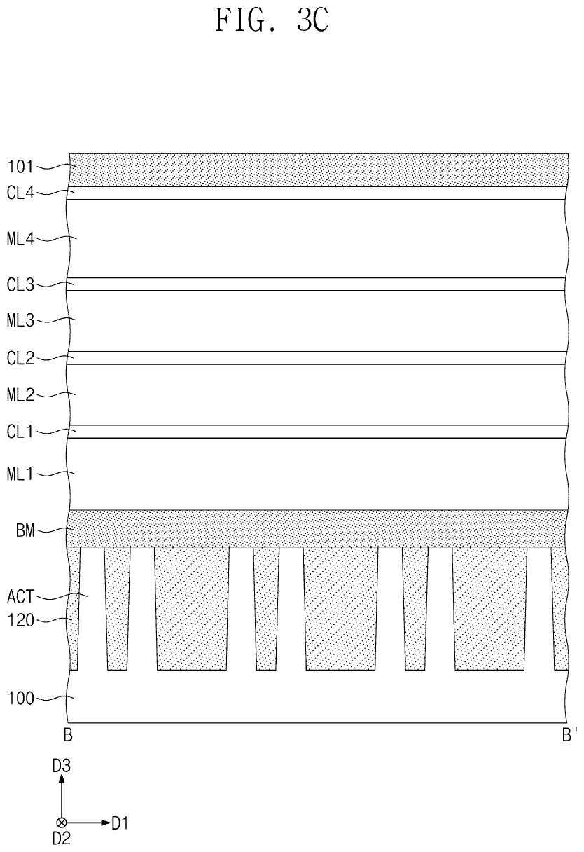

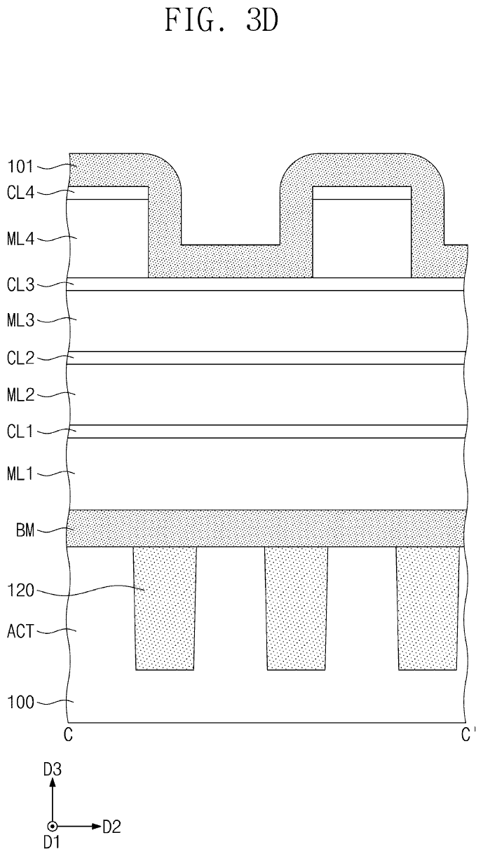

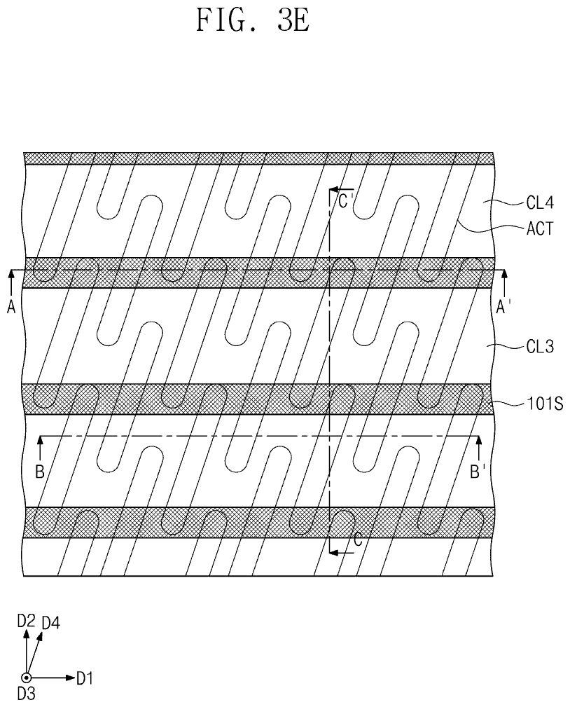

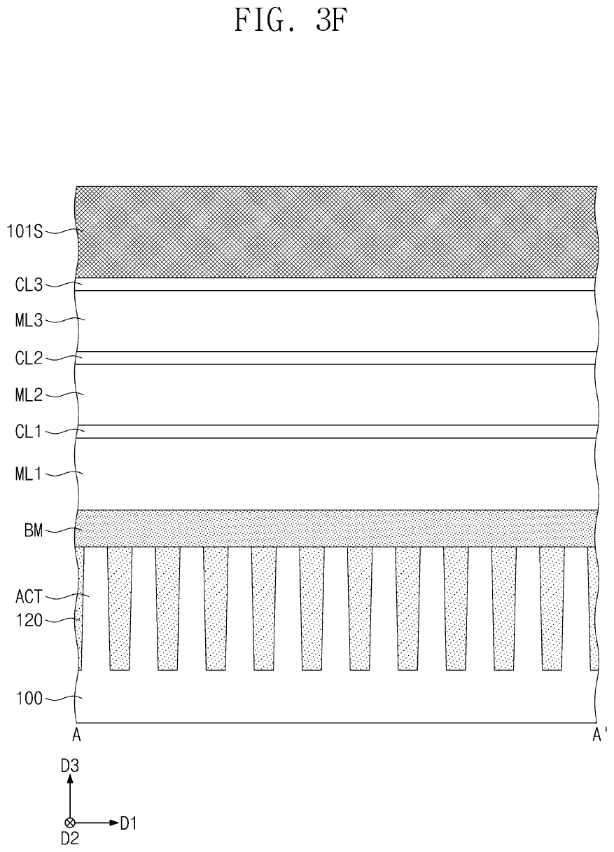

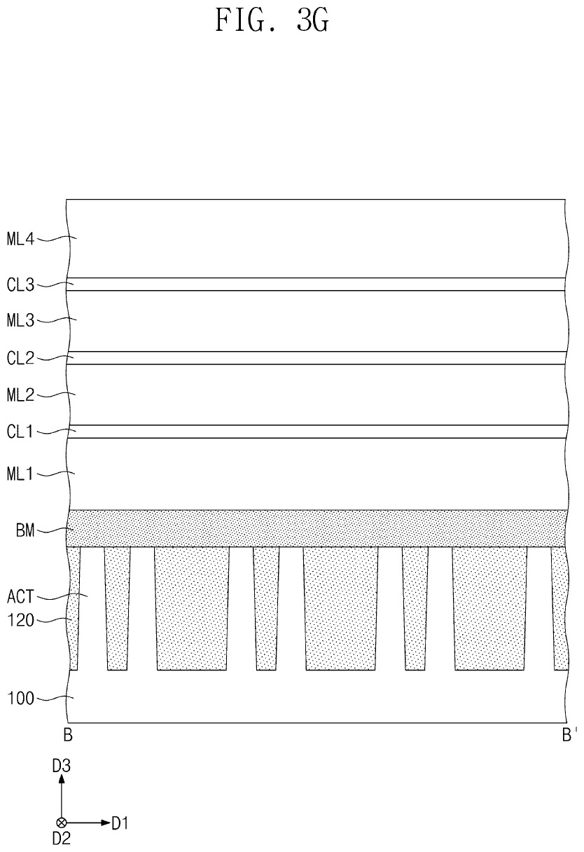

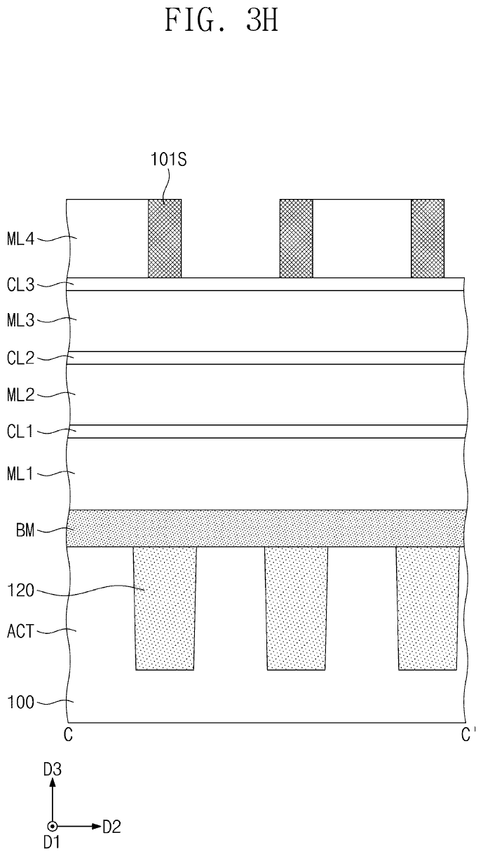

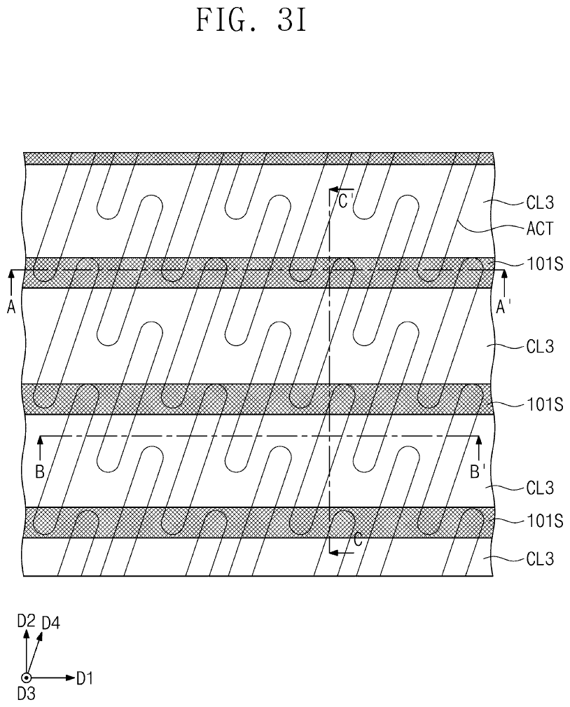

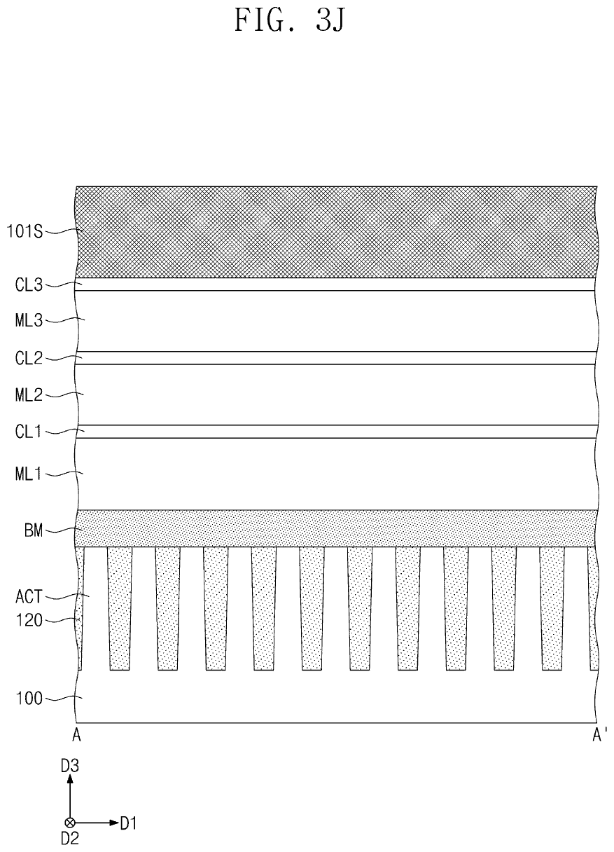

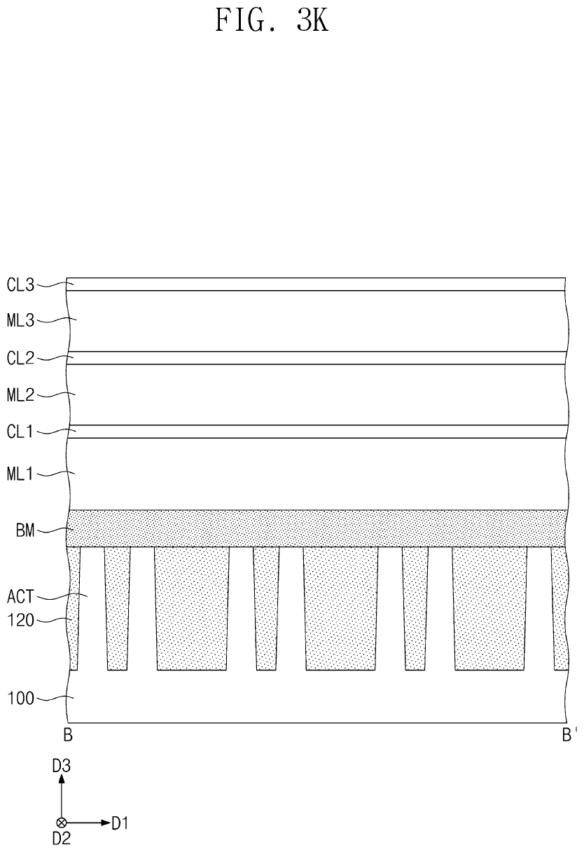

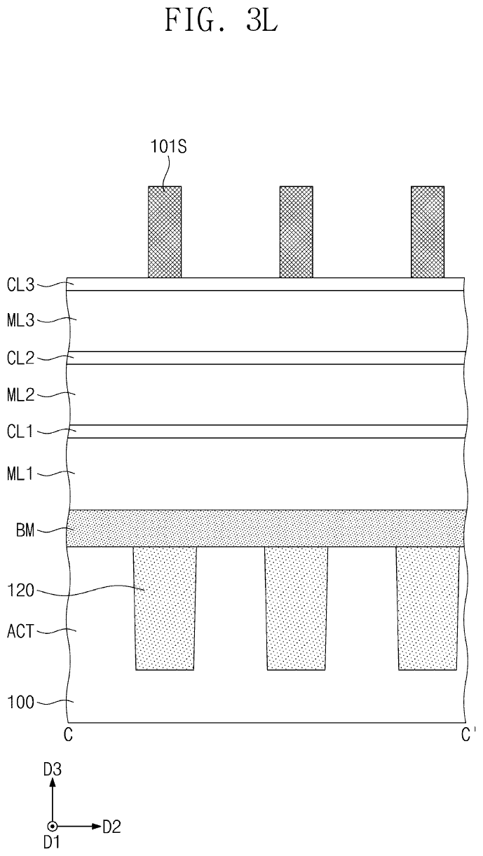

Referring to FIGS. 1 and 3A to 3D, the substrate 100 may be provided thereon with a base mask BM, a first mask layer ML1, a first capping layer CL1, a second mask layer ML2, a second capping layer CL2, a third mask layer ML3, a third capping layer CL3, a fourth mask layer ML4, and a fourth capping layer CL4 that are sequentially formed (S20).

Afterwards, the fourth mask layer ML4 and the fourth capping layer CL4 may be patterned (S30). The patterning of the fourth mask layer ML4 and the fourth capping layer CL4 may include partially removing the fourth mask layer ML4 and the fourth capping layer CL4 to form a plurality of patterns in the fourth mask layer ML4 and the fourth capping layer CL4.

After the patterning of the fourth mask layer ML4 and the fourth capping layer CL4, a first spacer layer 101 may be deposited. The first spacer layer 101 may be conformally deposited along an exposed top surface of the third mask layer ML3, an exposed lateral surface of the fourth mask layer ML4, and an exposed top surface of the fourth capping layer CL4. The first spacer layer 101 may have a deposition thickness that is determined in consideration of width of a trench TR that will be finally formed.

The first spacer layer 101 may be formed by atomic layer deposition (ALD). The first spacer layer 101 may include silicon oxide or silicon nitride. The first spacer layer 101 may include a material having an etch selectivity with respect to the fourth mask layer ML4. The fourth mask layer ML4 may include, for example, one of a polycrystalline silicon layer, an amorphous carbon layer (ACL), and a spin-on-hardmask (SOH) layer. The fourth capping layer CL4 may include, for example, silicon nitride (SiN) or silicon oxynitride (SiON).

Referring to FIGS. 1 and 3A to 3H, the first spacer layer 101 may be etched to form first spacers 101S (S40). The fourth capping layer CL4 may be removed which is patterned simultaneously with the etching of the first spacer layer 101. The patterned fourth mask layer ML4 and the first spacers 101S may remain on the third capping layer CL3. The first spacers 101S may be disposed on the sidewalls of the fourth mask layer ML4. The third capping layer CL3 may be exposed between neighboring first spacers 101S.

Referring to FIGS. 1 and 3I to 3L, the patterned fourth mask layer ML4 may be selectively removed.

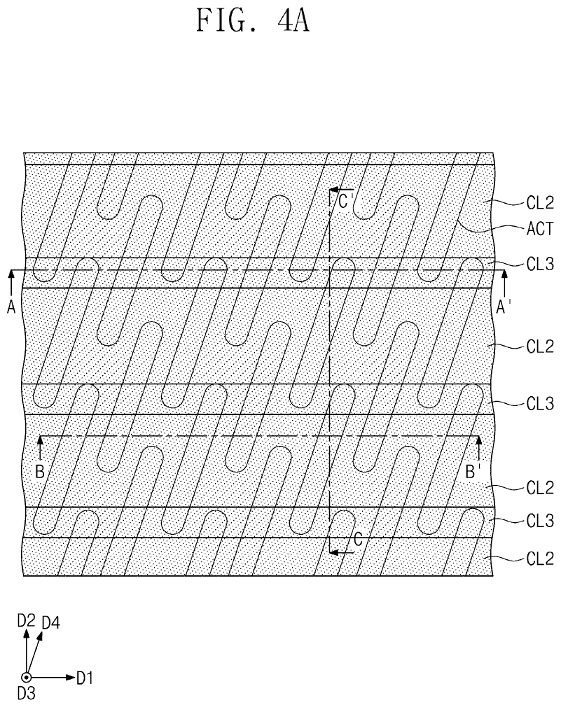

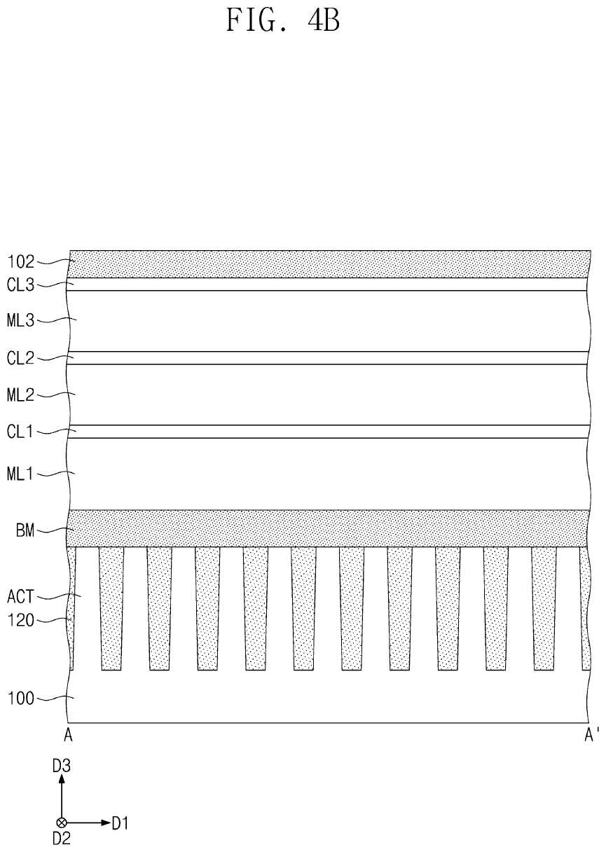

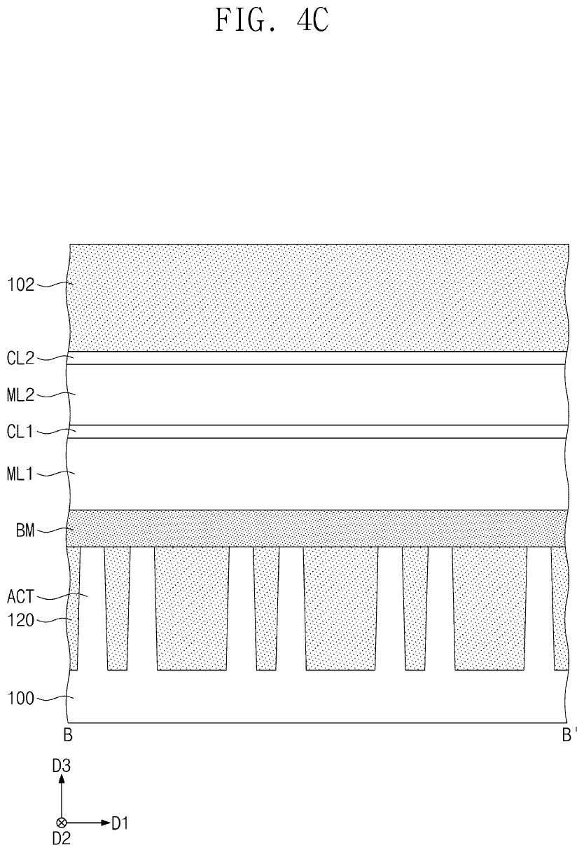

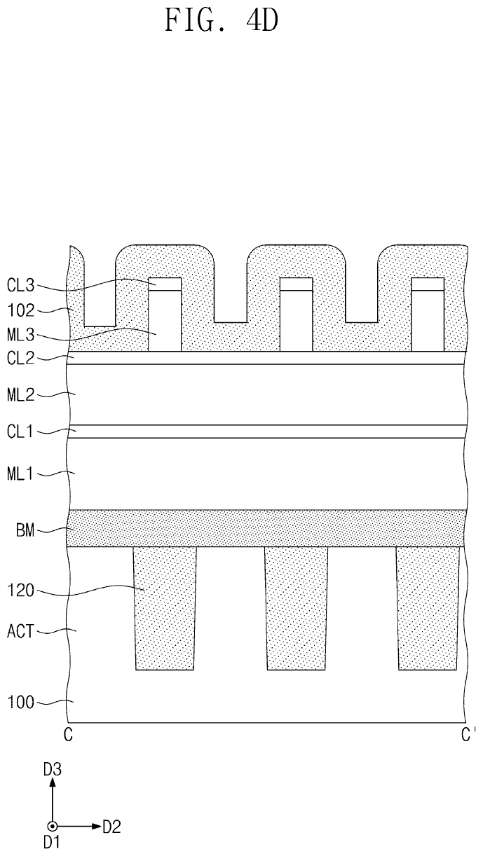

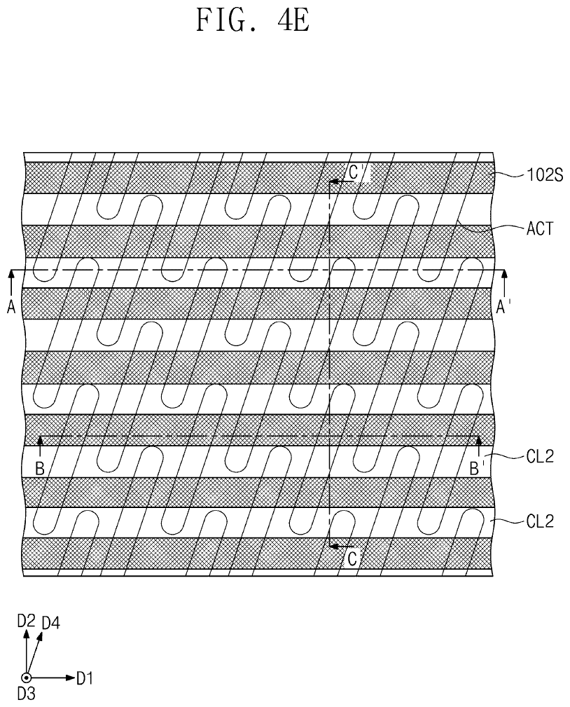

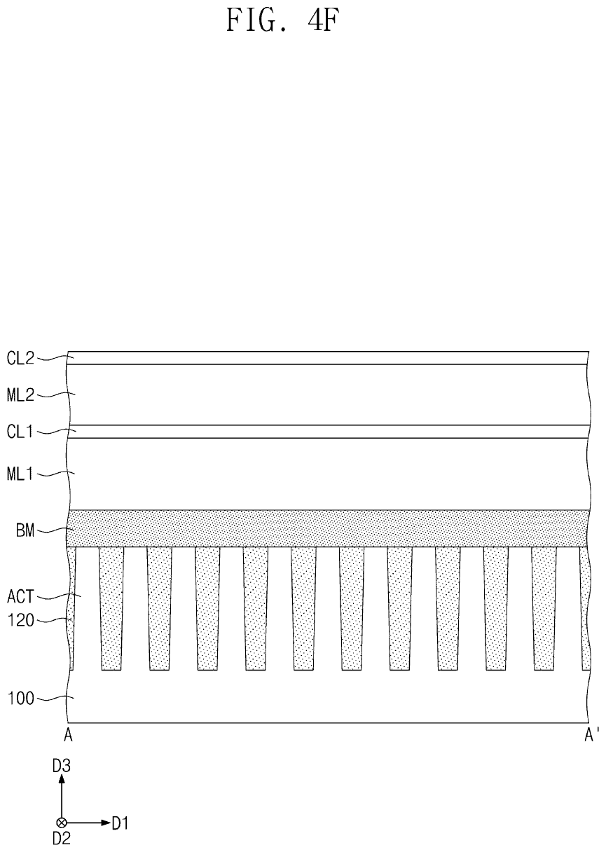

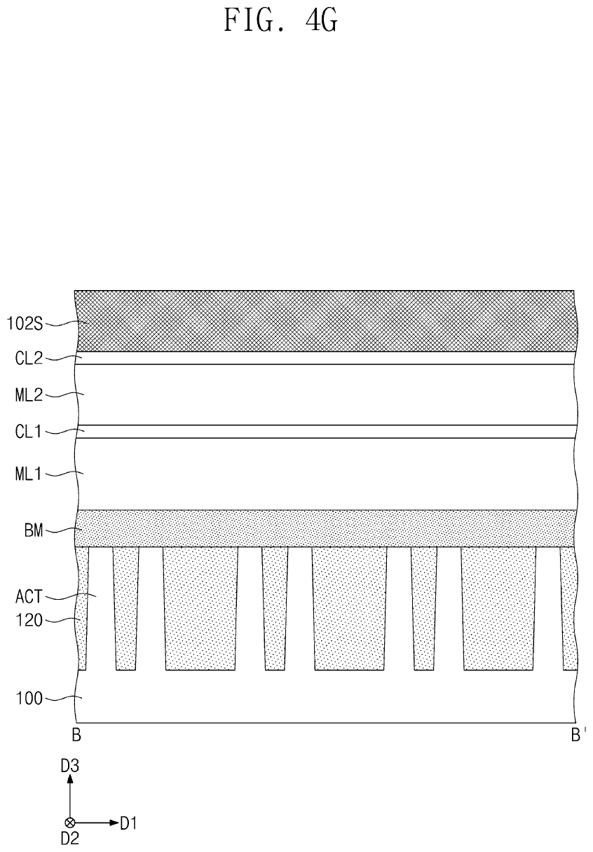

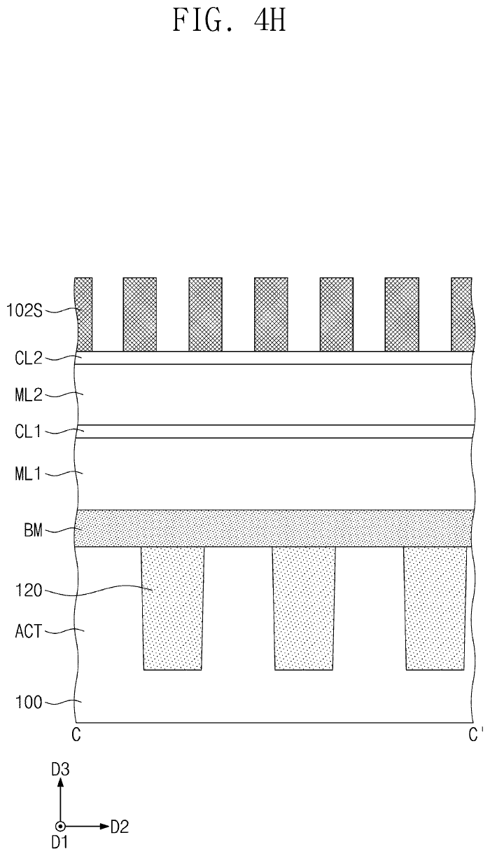

Referring to FIGS. 1 and 4A to 4D, the first spacers 101S may be used as a mask to pattern the third mask layer ML3 and the third capping layer CL3 (S50).

The patterning of the third mask layer ML3 and the third capping layer CL3 may include partially removing the third mask layer ML3 and the third capping layer CL3 to form a plurality of patterns in the third mask layer ML3 and the third capping layer CL3.

After the patterning of the third mask layer ML3 and the third capping layer CL3, a second spacer layer 102 may be deposited. The second spacer layer 102 may be conformally deposited along an exposed top surface of the second mask layer ML2, an exposed lateral surface of the third mask layer ML3, and an exposed top surface of the third capping layer CL3. The second spacer layer 102 may have a deposition thickness that is determined in consideration of width of a trench TR that will be finally formed.

Referring to FIGS. 1 and 4E to 4H, like the formation of the first spacers 101S, second spacers 102S may be formed on the sidewalls of the patterned third mask layer ML3 (S60). Afterwards, the patterned third mask layer ML3 may be selectively removed. The second spacers 102S may be spaced apart from each other in the second direction D2 and may extend in the first direction D1.

Referring to FIGS. 1 and 5A to 5E, the second spacers 102S may be used as a mask to pattern the second mask layer ML2 and the second capping layer CL2 (S70). In an embodiment, the second mask layer ML2 and the second capping layer CL2 that are patterned may have each have a width same as that of the second spacer 102S. In an embodiment, the patterned second mask layer ML2 may have a width of about 60 Å to about 70 Å.

After the patterning of the second mask layer ML2 and the second capping layer CL2, a third spacer layer 103 may be formed. The third spacer layer 103 may be deposited along an exposed top surface of the first mask layer ML1, an exposed lateral surface of the second mask layer ML2, and an exposed top surface of the second capping layer CL2. The third spacer layer 103 may be deposited to completely fill a space between neighboring sidewalls of the patterned second mask layer ML2. In this description, the phrase “completely fill” may mean that, between the sidewalls of neighboring patterned second mask layers ML2, the third spacer layer 103 is formed to be located at the same level as that of a top surface of the second mask layer ML2. In this case, the third spacer layer 103 may have a recess RCR on a top end thereof. A lowermost portion of the recess RCR may be located at a higher level than that of a top surface of the second capping layer CL2.

The third spacer layer 103 may include an upper portion 103_UP located at a higher level than that of the top surface of the second mask layer ML2, and may also include a plurality of lower portions 103_LP connected to the upper portion 103_UP. The third spacer layer 103 may have a first curved surface CS1 and a second curved surface CS2 that are in contact with each other. A contact point CP between the first and second curved surfaces CS1 and CS2 may be disposed between the patterned second mask layers ML2. For example, the contact point CP may be over a portion of the first capping layer CL1 exposed by the patterned second mask layers ML2 such that the contact point CP may be between patterns of the patterned second mask layers ML2 in a plan view. The contact point CP between the first and second curved surfaces CS1 and CS2 may be located at a higher level than that of the top surface of the second capping layer CL2. The contact point CP may overlap the lower portion 103_LP of the third spacer layer 103. In an embodiment, the third spacer layer 103 may include a seam therein.

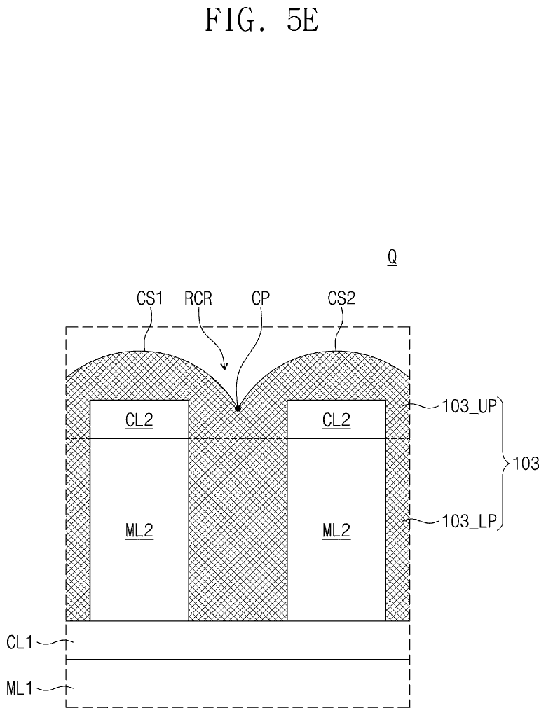

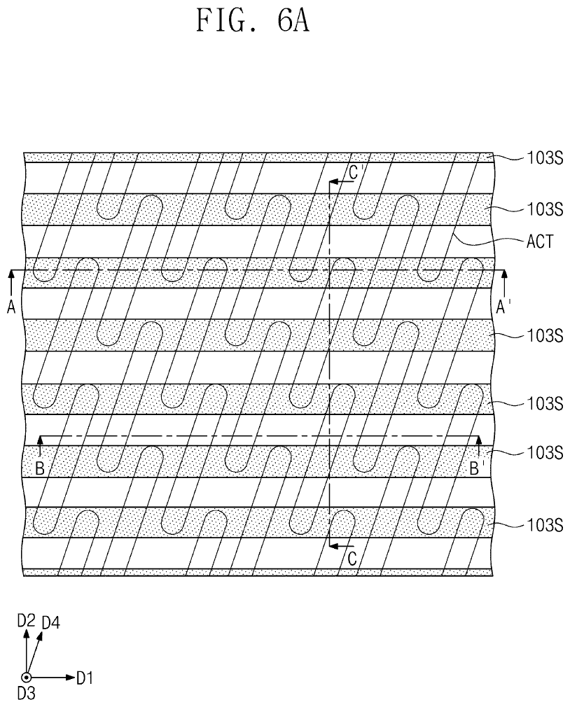

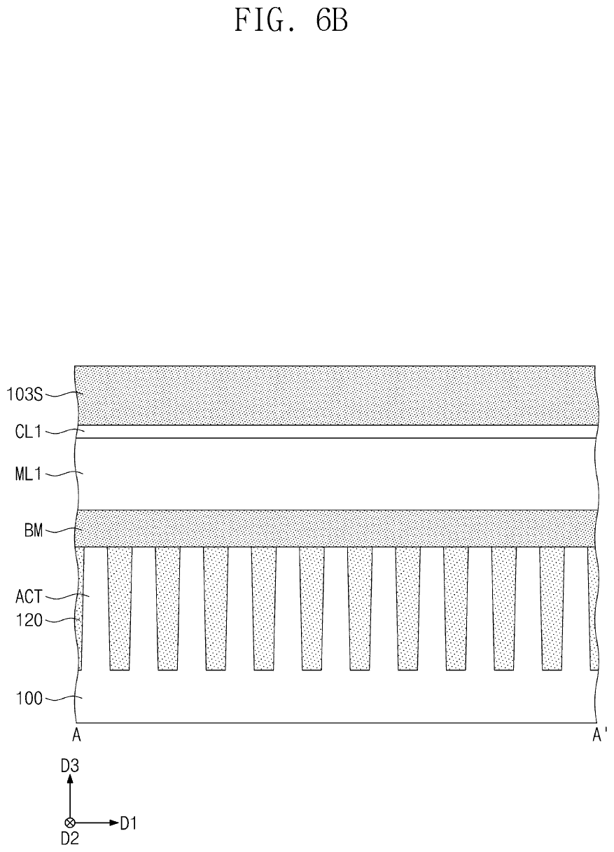

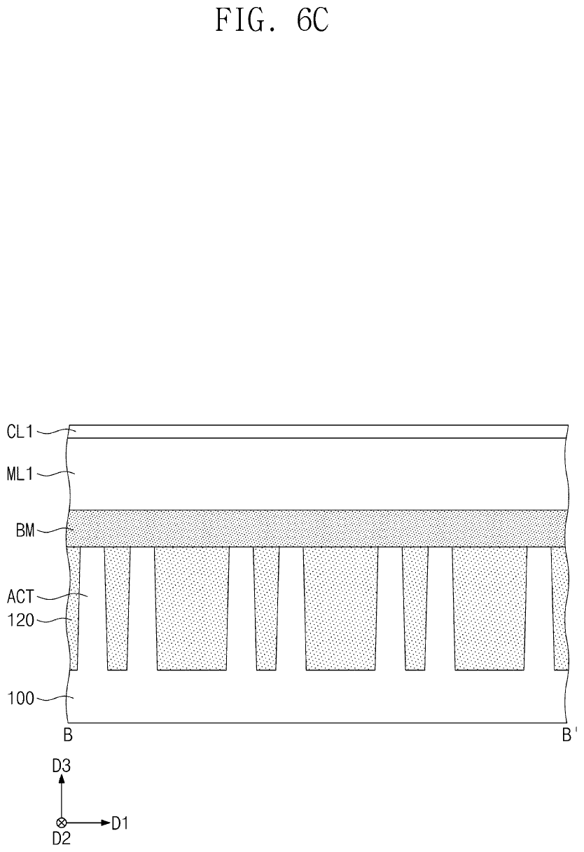

Referring to FIGS. 1 and 6A to 6D, a removal action may be performed on the upper portion 103_UP of the third spacer layer 103 and the patterned second capping layer CL2; consequently, only the patterned second mask layer ML2 and the lower portions 103_LP of the third spacer layer 103 may be left afterwards. The remaining lower portions 103_LP of the third spacer layer 103 may be defined as third spacers 103S (S80). Afterwards, the patterned second mask layer ML2 may be selectively removed. The patterned second mask layer ML2 may be removed to for an opening between the third spacers 103S. The third spacers 103S may be spaced apart from each other in the second direction D2 and may extend in the first direction D1. In an embodiment, each of the third spacers 103S may have a width greater than that of the patterned second mask layer ML2. For example, the third spacer 103S may have a width of about 190 Å to about 230 Å.

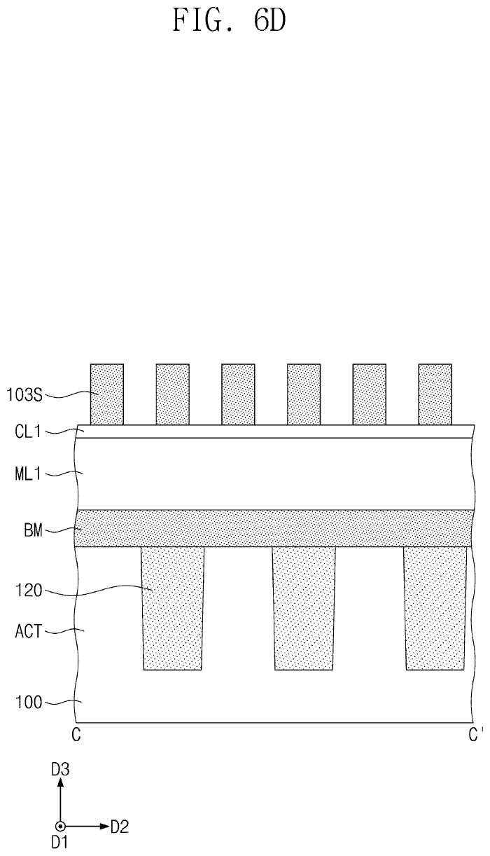

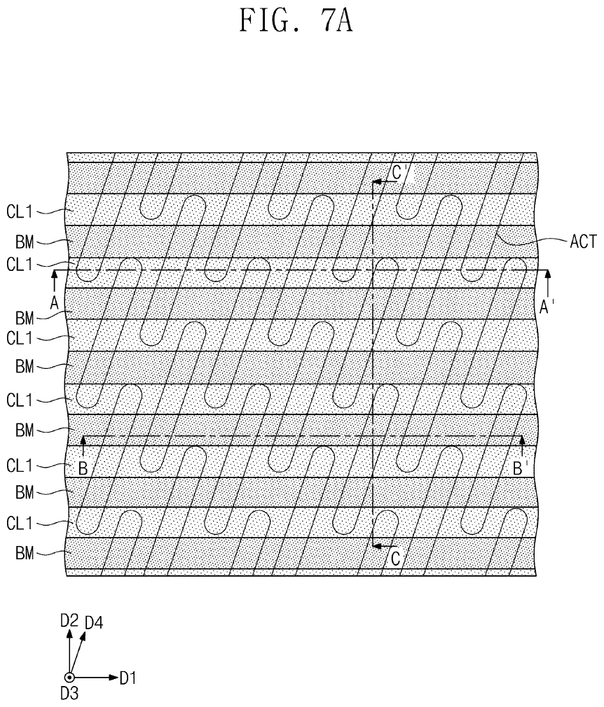

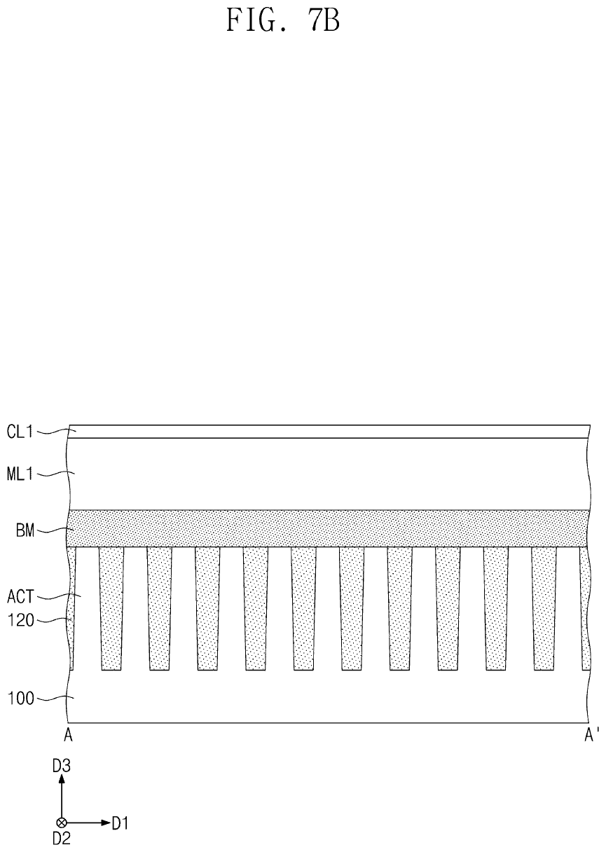

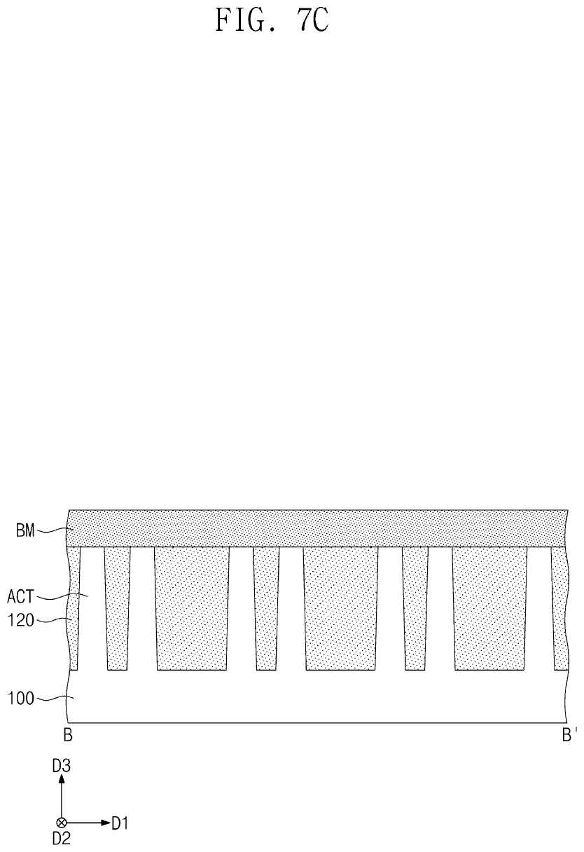

Referring to FIGS. 1 and 7A to 7D, the third spacers 103S may be used as a mask to pattern the first mask layer ML1 and the first capping layer CL1 (S90). The first mask layer ML1 and the first capping layer CL1 may be patterned through the opening between the third spacers 103S. In an embodiment, the patterned first capping layer CL1 may have a top surface whose width is the same as that of the third spacer 103S. The patterned first mask layer ML1 may have an inclined sidewall. In an embodiment, the first mask layer ML1 may be an amorphous carbon layer (ACL).

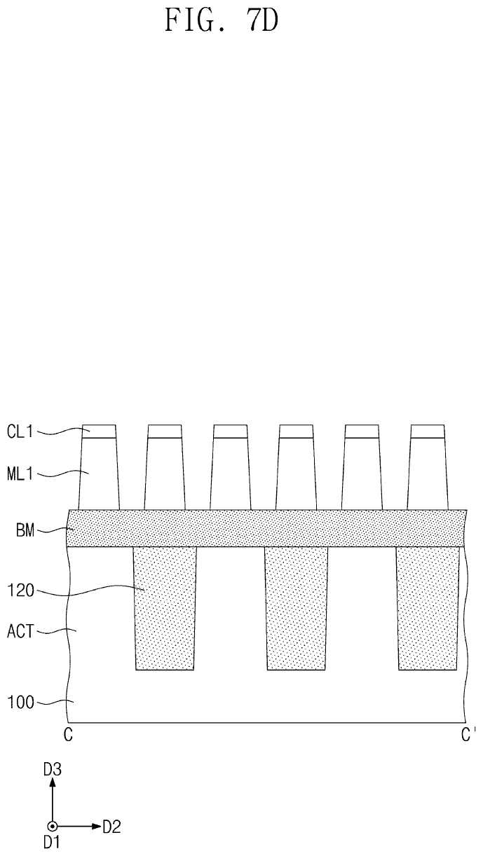

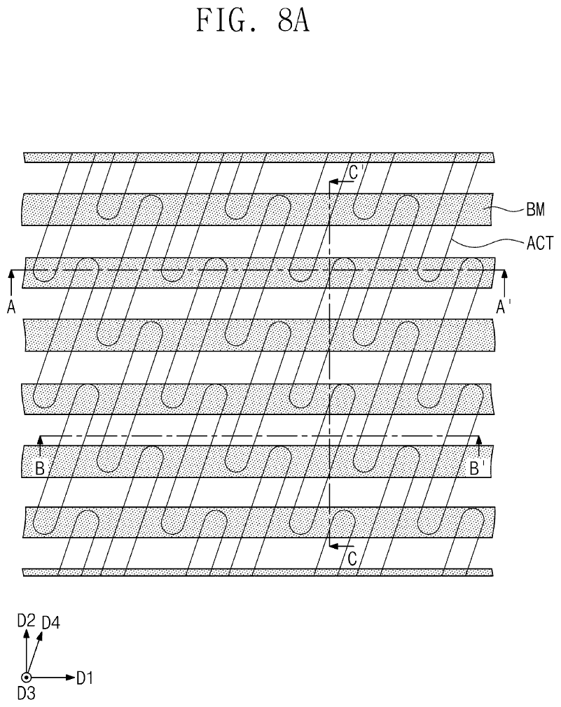

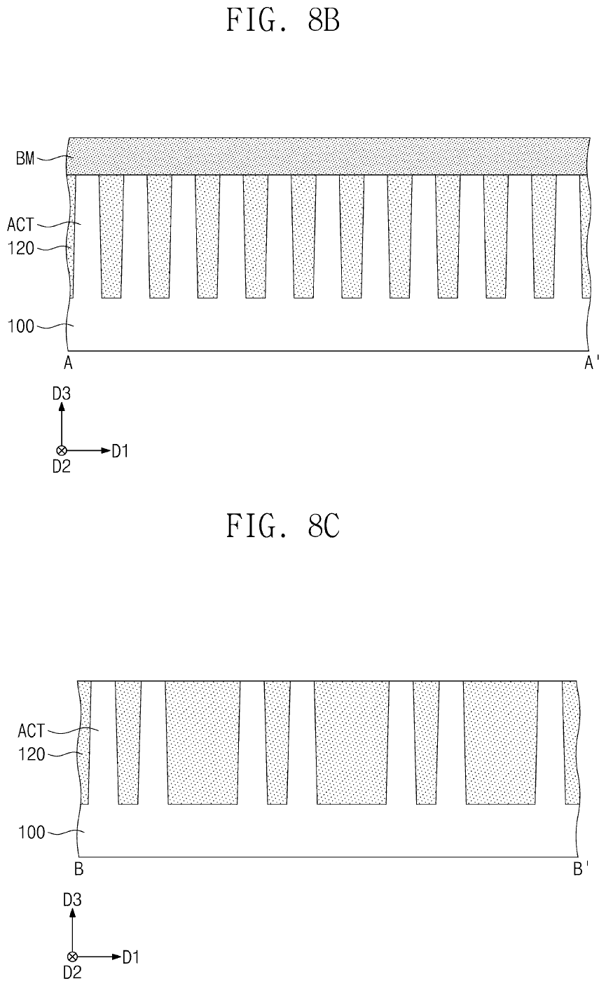

Referring to FIGS. 1 and 8A to 8D, the first mask layer ML1 and the first capping layer CL1 that are patterned may be used as a mask to pattern the base mask BM (S100). The patterned base masks BM may be spaced apart from each other in the second direction D2 and may extend in the first direction D1.

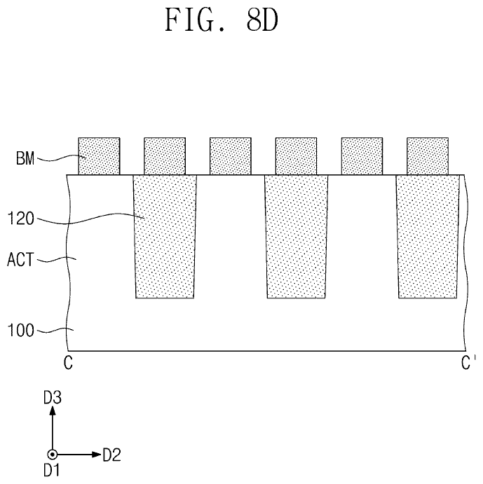

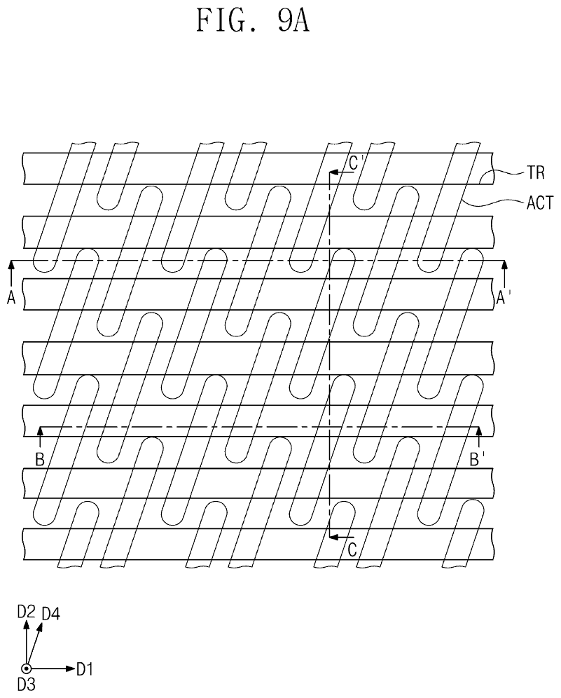

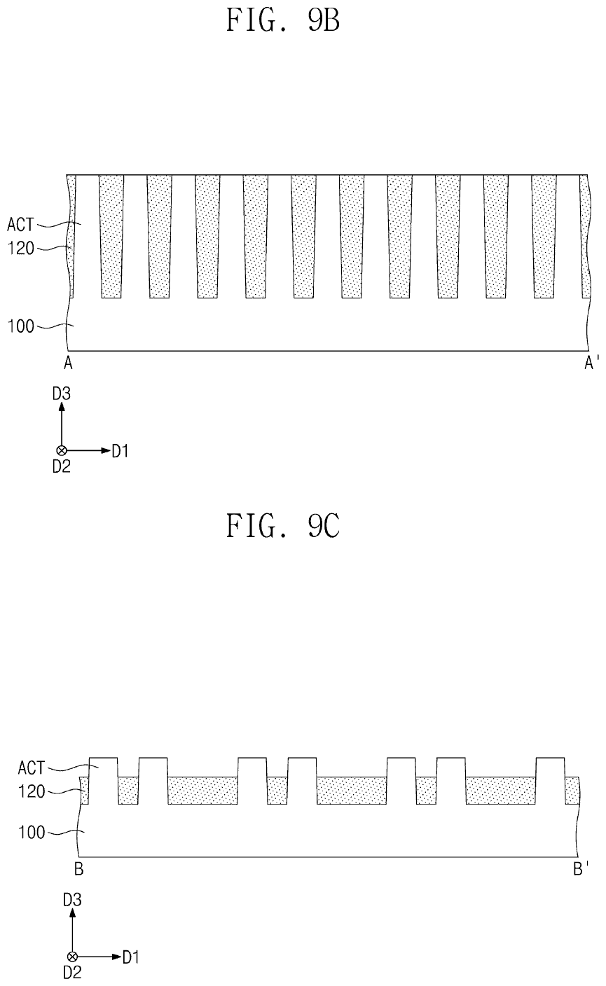

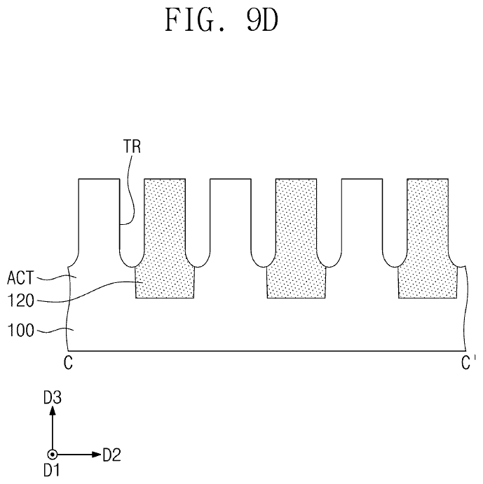

Referring to FIGS. 1 and 9A to 9D, the patterned base mask BM may be used as an etching mask to etch upper portions of the active patterns ACT and an upper portion of the device isolation pattern 120. Therefore, a trench TR may be formed (S110). A plurality of trenches T may extend in the first direction D1 and may be spaced apart from each other in the second direction D2. For example, a pair of trenches TR that neighbor in the second direction D2 may run in the first direction D1 across each of the active patterns ACT.

Each of the trenches TR may have an uneven structure on a bottom surface thereof.

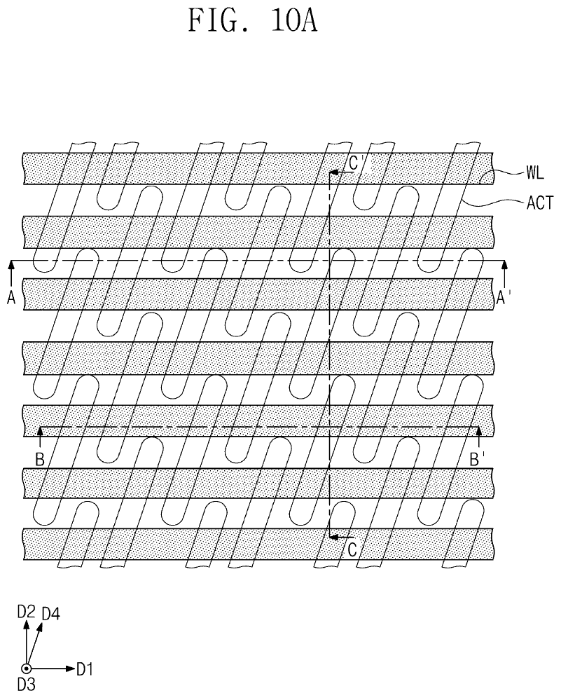

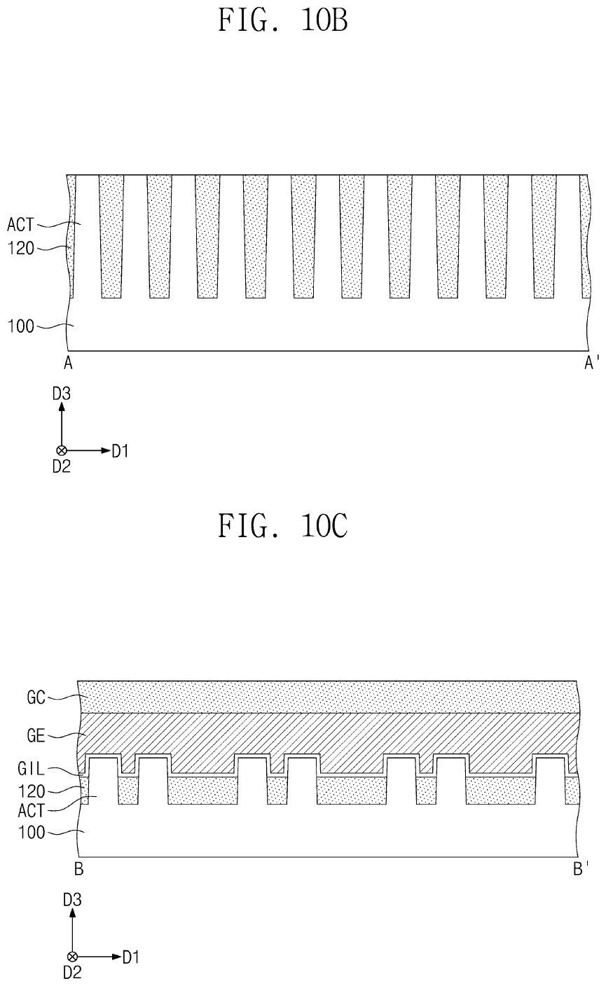

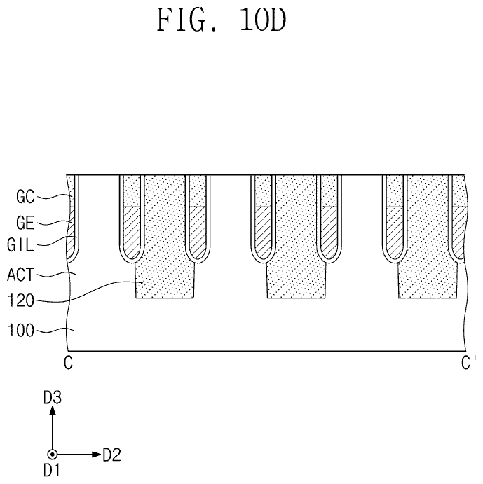

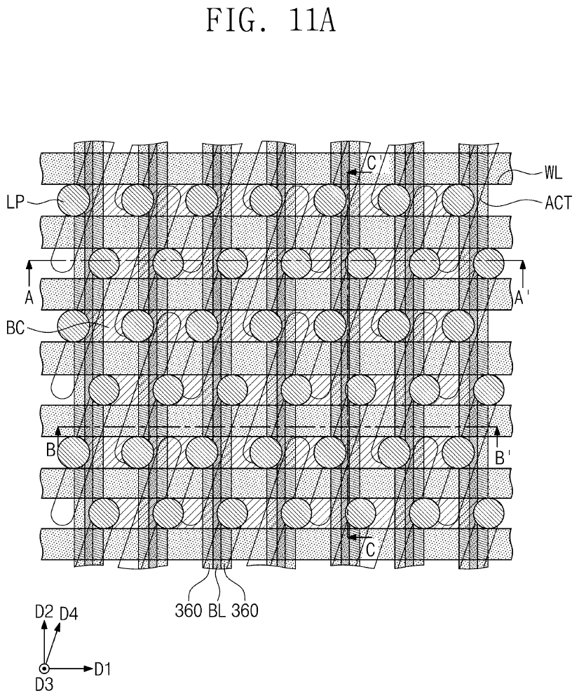

Referring to FIGS. 10A, 10B, 10C, and 10D, a gate dielectric layer GIL may be conformally formed on an entire surface of the substrate 100. For example, the gate dielectric layer GIL may be conformally formed in the trenches TR, and may extend onto top surfaces of the active patterns ACT and a top surface of the device isolation pattern 120. The gate dielectric layer GIL may have on its bottom surface an uneven structure along the trench TR. The gate dielectric layer GIL may be formed by physical vapor deposition (PVD), chemical vapor deposition (CVD), or atomic layer deposition (ALD). The gate dielectric layer GIL may include at least one selected from silicon oxide, high-k dielectric, and any combination thereof.

Thereafter, a gate electrode GE may be formed in the trench TR. A plurality of gate electrodes GE may be correspondingly formed in the trenches TR. The gate electrodes GE may be formed on the gate dielectric layer GIL. The gate electrode GE may include a conductive material. A lower portion of the trench TR in which the gate dielectric layer GIL is formed may be filled with a conductive material to form the gate electrode GE. The gate electrode GE may be a single or multiple layer including metal, metal nitride, or impurity-doped polysilicon.

The trench TR may have a remaining portion in which the gate electrode GE is not formed, and the remaining portion of the trench TR may be filled with a dielectric material to form a gate capping pattern GC. The gate capping pattern GC may be formed on the gate electrode GE. The formation of the gate capping pattern GC may include forming a gate capping layer (not shown) that fills the remaining portion of the trench TR and covers the top surfaces of the active patterns ACT and the top surface of the device isolation pattern 120, and then removing an upper portion of the gate capping layer to form the gate capping pattern GC. A gate structure WL may be constituted by the gate electrode GE, the gate dielectric layer GIL, and the gate capping pattern GC. The gate structure WL may be formed in the trench TR (S120).

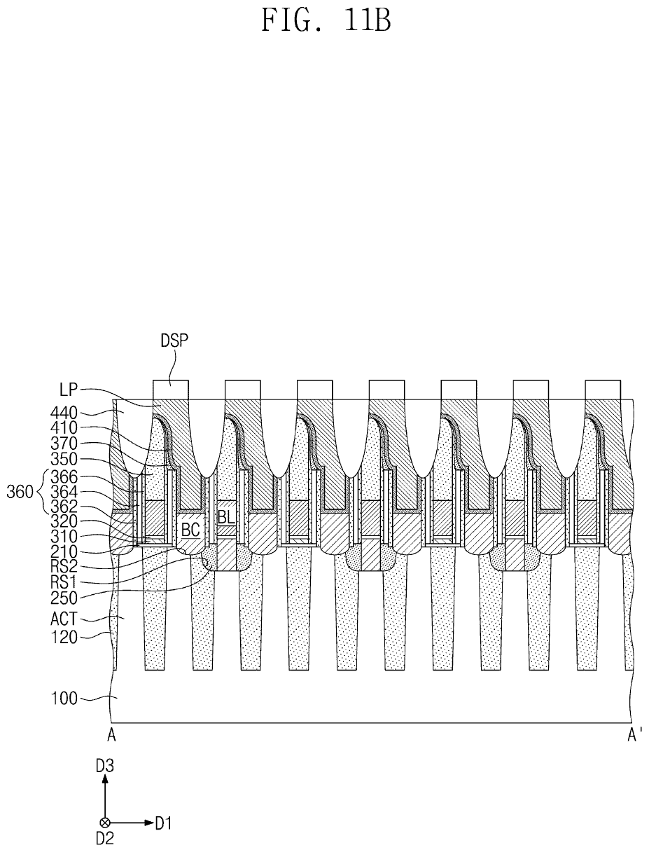

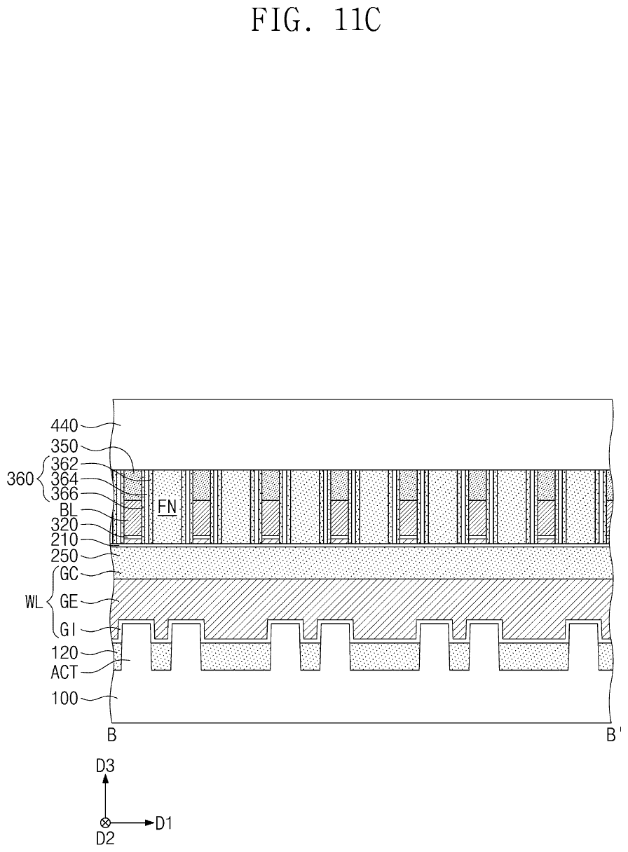

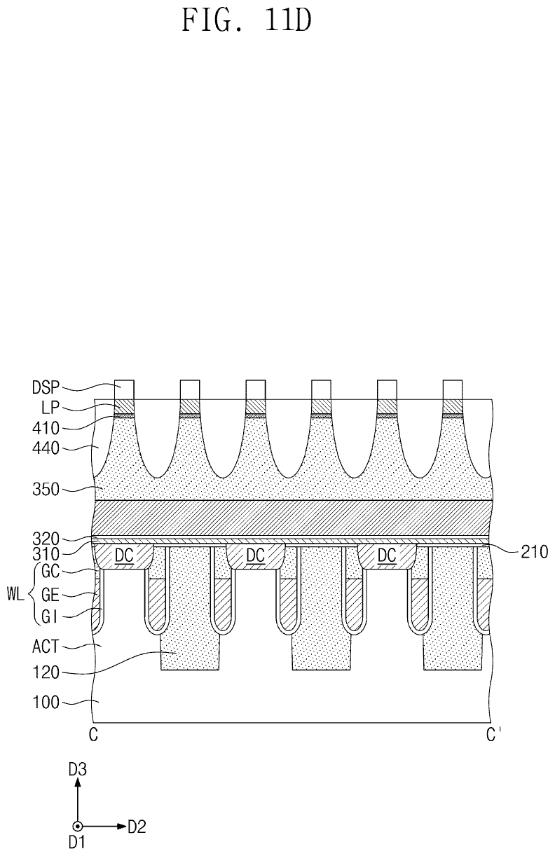

Referring to FIGS. 11A to 11D, a buffer layer (not shown) and a polysilicon layer (not shown) may be formed to cover the active patterns ACT and the device isolation pattern 120, and a first recess RS1 may be formed in each of the active patterns ACT and the device isolation pattern 120. In this step, the buffer layer and the polysilicon layer may be partially removed to form a buffer pattern 210 and a polysilicon pattern 310. The buffer pattern 210 may include, for example, at least one selected from silicon oxide, silicon nitride, silicon oxynitride, or any combination thereof. The polysilicon pattern 310 may include, for example, a polysilicon layer.

A bit-line contact DC, a bit line BL, and a bit-line capping pattern 350 may be formed in the first recess RS1. The formation of the bit-line contact DC, the bit line BL, and the bit-line capping pattern 350 may include forming a bit-line contact layer (not shown) to fill the first recess RS1, sequentially forming a bit line layer (not shown) and a bit-line capping layer (not shown) on the bit-line contact layer, and etching the bit-line contact layer, the bit line layer, and the bit-line capping layer to form the bit-line contact DC, the bit line BL, and the bit-line capping pattern 350. In this step, a partial inside of the first recess RS1 may be outwardly exposed again. After that, a buried pattern 250 may be formed to fill an unoccupied portion of the first recess RS1. For example, the bit-line contact DC may include polysilicon. The bit line BL may include at least one selected from tungsten, rubidium, molybdenum, titanium, and any combination thereof. The bit-line capping pattern 350 may include silicon nitride. During the formation of the bit line BL, a first ohmic pattern 320 may further be formed between the bit line BL and the bit-line contact DC and between the bit line BL and the polysilicon pattern 310. The first ohmic pattern 320 may include metal silicide.

A bit-line spacer 360 may be formed to cover a lateral surface of the bit line BL and a lateral surface of the bit-line capping pattern 350. The formation of the bit-line spacer 360 may include sequentially forming a first bit-line spacer 366, a second bit-line spacer 364, and a third bit-line spacer 362 that conformally cover the lateral surface of the bit line BL and the lateral surface of the bit-line capping pattern 350. For example, the first, second, and third bit-line spacers 366, 364, and 362 may each include at least one selected from silicon nitride, silicon oxide, silicon oxynitride, and any combination thereof. For another example, the second bit-line spacer 364 may include an air gap that separates the first and third bit-line spacers 366 and 362 from each other.

Storage node contacts BC and fence patterns FN may be formed between neighboring bit lines BL. The storage node contacts BC and the fence patterns FN may be arranged alternately along the first direction D1. Each of the storage node contacts BC may fill a second recess RS2, and may be electrically connected to a second impurity region 112 that corresponds to the second recess RS2. The fence patterns FN may be formed at positions that vertically overlap the gate structures WL. For example, the storage node contacts BC may be formed, and thereafter the fence patterns FN may be formed between the storage node contacts BC. For another example, the fence patterns FN may be formed, and thereafter the storage node contacts BC may be formed between the fence patterns FN. The storage node contacts BC may include at least one selected from impurity-doped polysilicon, impurity-undoped polysilicon, metal, and any combination thereof. The fence patterns FN may include silicon nitride.

During the formation of the storage node contacts BC, an upper portion of the bit-line spacer 360 may be partially removed. Therefore, a spacer capping pattern 370 may further be formed at a position where the bit-line spacer 360 is removed. For example, the spacer capping pattern 370 may include silicon nitride. Afterwards, a barrier pattern 410 may be formed to conformally cover the bit-line spacer 360, the spacer capping pattern 370, and the storage node contact BC. The barrier pattern 410 may include, for example, conductive metal nitride.

Landing pads LP may be formed on the storage node contacts BC. The formation of the landing pads LP may include sequentially forming a landing pad layer (not shown) and mask patterns (not shown) that cover top surfaces of the storage node contacts BC, and using the mask patterns as an etching mask to perform an anisotropic etching process to separate the landing pad layer into a plurality of landing pads LP. The barrier pattern 410, the bit-line spacer 360, and the bit-line capping pattern 350 may further be partially etched and outwardly exposed. An upper portion of the landing pad LP may be shifted in the second direction D2 from the storage node contact BC. For example, the landing pad LP may include a metallic material, such as tungsten, titanium, and tantalum.

According to some embodiments, the etching process of the landing pad layer may expose the second bit-line spacer 364. The etching process of the second bit-line spacer 364 may further be performed on the exposed portion of the second bit-line spacer 364, and eventually the second bit-line spacer 364 may include an air gap. Inventive concepts, however, are not limited thereto.

After that, a filling pattern 440 may be formed to cover exposed portions and to surround each of the landing pads LP, and a data storage pattern DSP may be formed on each of the landing pads LP.

For example, the data storage pattern DSP may be a capacitor including a bottom electrode, a dielectric layer, and a top electrode. In this case, a semiconductor memory device according to inventive concepts may be a dynamic random access memory (DRAM). For another example, the data storage pattern DSP may include a magnetic tunnel junction pattern. In this case, a semiconductor memory device according to inventive concepts may be a magnetic random access memory (MRAM). For another example, the data storage pattern DSP may include a phase change material or a variable resistance material. In this case, a semiconductor memory device according to inventive concepts may be a phase change random access memory (PRAM) or a resistive random access memory (ReRAM). This is, however, merely an example, and inventive concepts are not limited thereto. The data storage pattern DSP may include various structures and/or materials capable of storing data.

According to inventive concepts, a hard spacer may be used as a mask to form a recess on a substrate, and thus void failure may be avoided and collapse of the mask may be limited and/or prevented in fabricating a semiconductor device.

According to inventive concepts, an ALD spacer having high strength may be used to etch an SOH mask layer having low strength, and therefore void failure may be suppressed in fabricating a semiconductor device.

In addition, a spacer may be used as a mask to fabricate a semiconductor device, and accordingly a semiconductor device may decrease in process defects and increase in reliability.

The aforementioned description provides some embodiments for explaining inventive concepts. Therefore, inventive concepts are not limited to the embodiments described above, and it will be understood by one of ordinary skill in the art that variations in form and detail may be made therein without departing from the spirit and essential features of inventive concepts.

What is claimed is:

1. A method of fabricating a semiconductor device, the method comprising:
forming an active pattern on a substrate;
sequentially forming on the substrate a base mask, a first mask layer, a first capping layer, a second mask layer, a second capping layer, a third mask layer, a third capping layer, a fourth mask layer, and a fourth capping layer;
patterning the fourth mask layer and the fourth capping layer, the patterning the fourth mask layer providing a patterned fourth mask layer;
forming a plurality of first spacers on sidewalls of the patterned fourth mask layer;
using the first spacers as a mask to pattern the third mask layer and the third capping layer such that a patterned third mask layer and a patterned third capping layer are provided;
forming a plurality of second spacers on sidewalls of the patterned third mask layer;
using the second spacers as a mask to pattern the second mask layer and the second capping layer such that a patterned second mask layer and a patterned second capping layer are provided;
forming a plurality of third spacers on sidewalls of the patterned second mask layer;
using the third spacers as a mask to pattern the first mask layer and the first capping layer such that a patterned first mask layer and a patterned first capping layer are provided;
using the patterned first mask layer and the patterned first capping layer as a mask to pattern the base mask such that a patterned base mask is provided;
using the patterned base mask as a mask to etch a trench in the active pattern; and
forming a gate structure in the trench, wherein
the forming the plurality of third spacers includes forming a spacer layer to completely fill a space between the sidewalls of the patterned second mask layer.

2. The method of claim 1, wherein a width of each of the plurality of third spacers is greater than a width of the patterned second mask layer.

3. The method of claim 1, wherein the using the third spacers as the mask to pattern the first mask layer and the first capping layer includes:
removing the patterned second mask layer to form an opening between the plurality of third spacers; and
patterning the first mask layer and the first capping layer through the opening.

4. The method of claim 1, wherein
the spacer layer has a first curved surface and a second curved surface that are in contact with each other,
a contact point between the first curved surface and the second curved surface is between patterns of the patterned second mask layer, and
a level of the contact point between the first curved surface and the second curved surface is higher than a level of a top surface of the second capping layer.

5. The method of claim 1, wherein the forming the gate structure in the trench includes:
conformally forming a gate dielectric layer in the trench;
forming a gate electrode on the gate dielectric layer; and
forming a gate capping pattern on the gate electrode.

6. The method of claim 1, further comprising:
before patterning the first mask layer and the first capping layer, removing the patterned second capping layer and the patterned second mask layer.

7. The method of claim 1, wherein the first mask layer includes an amorphous carbon layer (ACL).

8. The method of claim 1, wherein the the spacer layer includes an upper portion and a plurality of lower portions connected to the upper portion,
a level of the upper portion is higher than a level of a top surface of the patterned second mask layer,
the forming the plurality of third spacers includes removing the second capping layer and the upper portion of the spacer layer after forming the spacer layer.

9. The method of claim 1, wherein a width of the patterned second mask layer is in a range of about 60 Å to about 70 Å.

10. A method of fabricating a semiconductor device, the method comprising:
forming an active pattern on a substrate;
sequentially forming on the substrate a base mask, a first mask layer, a first capping layer, a second mask layer, a second capping layer, a third mask layer, and a third capping layer;
patterning the third mask layer and the third capping layer;
forming a plurality of first spacers on sidewalls of the third mask layer;
using the first spacers as a mask to pattern the second mask layer and the second capping layer such that a patterned second mask layer and a patterned second capping layer are provided;
forming a plurality of second spacers on sidewalls of the patterned second mask layer;
using the second spacers as a mask to pattern the first mask layer and the first capping layer such that a patterned first mask layer and a patterned first capping layer are provided;
using the patterned first mask layer and the patterned first capping layer as a mask to pattern the base mask such that a patterned base mask is provided; and
forming a trench in the active pattern using the patterned base mask as a mask, wherein
the forming the plurality of second spacers includes forming a spacer layer on the patterned second mask layer and the patterned second capping layer, and etching the spacer layer,
the spacer layer has a first curved surface and a second curved surface that are in contact with each other, and
a contact point between the first curved surface and the second curved surface is between patterns of the patterned second mask layer.

11. The method of claim 10, wherein
the spacer layer includes an upper portion and a plurality of lower portions connected to the upper portion,
a level of the upper portion is higher than a level of a top surface of the patterned second mask layer.

12. The method of claim 11, wherein each of the plurality of lower portions of the spacer layer is between patterns of the patterned second mask layer.

13. The method of claim 12, wherein the etching the spacer layer includes removing the upper portion of the spacer layer.

14. The method of claim 12, after forming the plurality of second spacers, further comprising:
removing the patterned second mask layer to expose the first capping layer.

15. The method of claim 11, wherein the contact point overlaps one of the plurality of lower portions of the spacer layer.

16. The method of claim 10, wherein the first capping layer includes SiON.

17. The method of claim 10, wherein a width of each of the plurality of second spacers is in a range of about 190 Å to about 230 Å.

18. The method of claim 10, wherein the spacer layer includes a seam therein.

19. A method of fabricating a semiconductor device, the method comprising:
forming an active pattern on a substrate;
sequentially forming on the substrate a base mask, a first mask layer, a first capping layer, a second mask layer, a second capping layer, a third mask layer, a third capping layer, a fourth mask layer, and a fourth capping layer;
patterning the fourth mask layer and the fourth capping layer, the patterning the fourth mask layer and the fourth capping layer providing a patterned fourth mask layer and a patterned fourth capping layer;
forming a plurality of first spacers on sidewalls of the patterned fourth mask layer and sidewalls of the patterned fourth capping layer;
removing the patterned fourth mask layer and the patterned fourth capping layer;
using the first spacers as a mask to pattern the third mask layer and the third capping layer such that a patterned third mask layer and a patterned third capping layer are provided;
forming a plurality of second spacers on sidewalls of the patterned third mask layer and sidewalls of the patterned third capping layer;
removing the patterned third mask layer and the patterned third capping layer;
using the second spacers as a mask to pattern the second mask layer and the second capping layer such that a patterned second mask layer and a patterned second capping layer are provided;
depositing a spacer layer that completely fills spaces between patterns of the patterned second mask layer and fills spaces between patterns of the patterned second capping layer;
removing an upper portion of the spacer layer to form a plurality of third spacers;
removing the patterned second mask layer and the patterned second capping layer;
using the third spacers as a mask to pattern the first mask layer and the first capping layer such that a patterned first mask layer and a patterned first capping layer are provided;
using the patterned first mask layer and the patterned first capping layer to pattern the base mask such that a patterned base mask is provided; and
using the patterned base mask to form a trench in the active pattern.

20. The method of claim 19, wherein
the spacer layer includes a plurality of lower portions connected to the upper portion, and
each of the lower portions of the spacer layer is between the patterns of the patterned second mask layer.
